(19) United States
(12) Patent Application Publication
(10) Pub. No.: US 2025/0266282 A1
(43) Pub. Date: Aug. 21, 2025

(54) METHOD OF TRANSPORTING SEMICONDUCTOR DEVICE AND CARRIER TAPE

(71) Applicant: Renesas Electronics Corporation, Tokyo (JP)

(72) Inventor: Kouichi OKAMOTO, Tokyo (JP)

(21) Appl. No.: 19/013,108

(22) Filed: Jan. 8, 2025

(30) Foreign Application Priority Data
Feb. 20, 2024 (JP) 2024-023986

(51) Int. Cl. H01L 21/683

(52) U.S. Cl. CPC H01L 21/6836; H01L 2221/68313

(57) ABSTRACT

A method of transporting a semiconductor device includes: a step of placing a semiconductor device in a pocket portion, a step of attaching the cover tape to the carrier tape so as to cover the semiconductor device placed in the pocket portion, and a step of transporting the carrier tape containing the semiconductor device. Here, the pocket portion includes: a plurality of corner portions where a step section is formed, and a plurality of side portions located between these corner portions and having a first protruding portion and a second protruding portion formed thereon. Also, a width of a tip portion of the second protruding portion is smaller than a width of the tip portion of the first protruding portion. Furthermore, a protrusion amount of the second protruding portion from the side portion is larger than a protrusion amount of the first protruding portion from the side portion.

### CROSS-REFERENCE TO RELATED APPLICATIONS

The disclosure of Japanese Patent Application No. 2024-023986 filed on Feb. 20, 2024, including the specification, drawings and abstract is incorporated herein by reference in its entirety.

### BACKGROUND

The present invention relates to a method of transporting a semiconductor device and to a carrier tape.

There are disclosed techniques listed below. [Patent Document 1] Japanese Unexamined Patent Application Publication No. 2018-002211

Patent Document 1 discloses accommodating a semiconductor device in an accommodating portion (pocket portion) of a carrier tape that has been embossed.

### SUMMARY

As methods of transporting semiconductor devices, there are methods using a tray made of resin and using a carrier tape. In the method using the tray, a manufactured semiconductor device is accommodated in a plurality of accommodating portions (pocket portions) provided in a matrix array on a surface of the tray. To prevent the semiconductor device from popping out of the accommodating portions during transportation of this tray, another tray is placed over the tray containing the semiconductor device, and they are transported in this state. In contrast, in the method using the carrier tape, after accommodating the manufactured semiconductor device in the accommodating portions of the carrier tape, to prevent the semiconductor device from popping out of the accommodating portions during transportation of this carrier tape, the semiconductor device is covered with a cover tape. Then, the carrier tape having a surface to which the cover tape is attached is wound onto a reel, and transported in this state. If it is desired to increase the number of semiconductor devices to be transported, the length of the carrier tape wound onto the reel can be increased.

The present inventors have been considering to transport the semiconductor device including a wiring board, such as BGA (Ball Grid Array) or LGA (Land Grid Array), by using the carrier tape. According to the review of the present inventors, it has been found that when transporting the semiconductor device by using the carrier tape, vibrations and shocks during the transportation of the carrier tape containing the semiconductor devices may cause foreign substances to be generated. These foreign substances are a part of the material composing the carrier tape. The generation of foreign substances may lead to a decrease in the reliability of the semiconductor device or may cause a problem when mounting the semiconductor device taken out from the carrier tape onto a mounting board. Therefore, a shape (structure) of the accommodating portion that can suppress the generation of foreign substances as much as possible is desired.

Other objects and novel features will become apparent from the description of this specification and the accompanying drawings.

A method of transporting a semiconductor device according to one embodiment includes: a step of placing a semiconductor device in a pocket portion of a carrier tape, a step of attaching a cover tape to the carrier tape so as to cover the semiconductor device placed in the pocket portion, and a step of transporting the carrier tape containing the semiconductor device. Here, the pocket portion includes: a plurality of corner portions where a step section is formed, and a plurality of side portions located between these corner portions and having a first protruding portion and a second protruding portion formed thereon. Moreover, a width of a tip portion of the second protruding portion is smaller than a width of the tip portion of the first protruding portion. Furthermore, a protrusion amount of the second protruding portion from the side portion is larger than a protrusion amount of the first protruding portion from the side portion.

A carrier tape according to one embodiment includes a pocket portion including: a plurality of corner portions where a step portion is formed, and a plurality of side portions located between these corner portions and where the first protruding portion and the second protruding portion are formed. Furthermore, a width of the tip portion of the second protruding portion is smaller than a width of the tip portion of the first protruding portion. Moreover, a protrusion amount of the second protruding portion from the side portion is larger than a protrusion amount of the first protruding portion from the side portion.

A method of transporting a semiconductor device according to one embodiment includes: a step of placing a semiconductor device in a pocket portion of a carrier tape, a step pf attaching a cover tape to the carrier tape so as to cover the semiconductor device placed in the pocket portion, and a step of transporting the carrier tape containing the semiconductor device. Here, the pocket portion includes: a plurality of corner portions having a notch portion, and a plurality of side portions located between these corner portions. Furthermore, a planar shape of two sides forming the notch portion draws an arc so as to curve from each of the first side portion and the second side portion, which are adjacent to the notch portion, towards an apex of the notch portion. Moreover, the notch portion is provided such that a distance between the two sides of the notch portion gradually decreases towards the apex of the notch portion.

According to the above embodiment, it is possible to suppress the reduction in reliability of the semiconductor device.

### BRIEF DESCRIPTION OF THE DRAWINGS

FIG. 1 is an upper surface view of a semiconductor device according to one embodiment.

FIG. 2 is a lower surface view of the semiconductor device shown in FIG. 1.

FIG. 3 is a cross-sectional view taken along line A-A in FIG. 1.

FIG. 4 is an enlarged plan view at a portion of a carrier tape according to one embodiment.

FIG. 5 is a cross-sectional view taken along a line B1-B1 in FIG. 4.

FIG. 6 is a cross-sectional view taken along a line B2-B2 in FIG. 4.

FIG. 7 is a cross-sectional view taken along a line B3-B3 in FIG. 4.

FIG. 8 is an enlarged plan view at the portion of the carrier tape after a step shown in FIG. 4.

FIG. 9 is a cross-sectional view taken along a line C1-C1 in FIG. 8.

FIG. 10 is a cross-sectional view taken along a line C2-C2 in FIG. 8.

FIG. 11 is a cross-sectional view taken along a line C3-C3 in FIG. 8.

FIG. 12 is an enlarged plan view at the portion of the carrier tape after a step shown in FIG. 8.

FIG. 13 is a cross-sectional view taken along a line D1-D1 in FIG. 12.

FIG. 14 is a cross-sectional view taken along a line D2-D2 in FIG. 12.

FIG. 15 is a cross-sectional view taken along a line D3-D3 in FIG. 12.

FIG. 16 is a view showing a state in which the carrier tape is wound on a reel after a step shown in FIG. 12.

FIG. 17 is a view showing a state in which the reel shown in FIG. 16 is accommodated in a moisture-proof bag.

FIG. 18 is a cross-sectional view of a carrier tape according to a modified example.

FIG. 19 is an enlarged plan view at a portion of a carrier tape according to another embodiment.

FIG. 20 is a cross-sectional view taken along a line E1-E1 in FIG. 19.

FIG. 21 is a cross-sectional view taken along a line E2-E2 in FIG. 19.

FIG. 22 is an enlarged plan view at the portion of the carrier tape after a step shown in FIG. 19.

FIG. 23 is a cross-sectional view taken along a line F1-F1 in FIG. 22.

FIG. 24 is a cross-sectional view taken along a line F2-F2 in FIG. 22.

FIG. 25 is an enlarged plan view at the portion of the carrier tape after a step shown in FIG. 22.

FIG. 26 is a cross-sectional view taken along a line G1-G1 in FIG. 25.

FIG. 27 is a cross-sectional view taken along a line G2-G2 in FIG. 25.

FIG. 28 is a cross-sectional view showing a state in which a semiconductor device is accommodated in an accommodating portion of a carrier tape according to an examined example.

FIG. 29 is a cross-sectional view showing a state of the carrier tape shown in FIG. 28 during transportation.

### DETAILED DESCRIPTION

### Description of Format, Basic Term and Usage in the Present Application

In this application, the description of embodiments is divided into multiple sections as necessary for convenience, but unless expressly stated otherwise, these are not independent and separate from each other, regardless of the order of description, and parts of a single example, where one part may be a detailed part of another or a part or all of a modified example. Also, in principle, descriptions of similar parts are omitted. Furthermore, each component in an embodiment is not essential, unless expressly stated otherwise, theoretically limited to that number, and obviously otherwise from the context.

Similarly, in the description of embodiments and the like, regarding materials, compositions, etc., saying “X consisting of A” does not exclude elements other than A, unless expressly stated otherwise and unless it is clear from the context that it is not the case. For example, regarding a component, it means “X including A as a main component” or the like. For instance, mentioning a “silicon member” does not limit it to pure silicon but includes members containing SiGe (Silicon Germanium) alloy and other multicomponent alloys with silicon as a main component, as well as other additives. Also, mentioning gold plating, Cu layer, nickel plating, etc., unless expressly stated otherwise, includes not only pure materials but also members containing gold, Cu, nickel, etc., as main components.

Furthermore, when specific values or quantities are mentioned, unless expressly stated otherwise, theoretically limited to that number, and obviously otherwise from the context, the values may exceed or be less than that specific number.

Also, in the figures of each embodiment, identical or similar parts are indicated by the same or similar symbols or reference numbers, and the description is not repeated in principle.

Moreover, in the attached drawings, hatching, etc., may be omitted in cross-sections when it would otherwise complicate the drawing or when the distinction from a void is clear. In this connection, even if the hole is closed in plan, the outline of the background may be omitted when it is obvious from the description or the like. Furthermore, even if not in cross-section, hatching or dot patterns may be applied to indicate that it is not a void or to indicate the boundary of a region.

The technology described in the following embodiments can be applied to a carrier tape in which a semiconductor device with a wiring substrate (a so-called substrate type semiconductor device) is accommodated. In this embodiment, as an example of the substrate type, a BGA typed semiconductor device is described, in which multiple solder balls are formed on multiple bump lands provided on the lower surface of the wiring substrate.

### First Embodiment

### Semiconductor Device

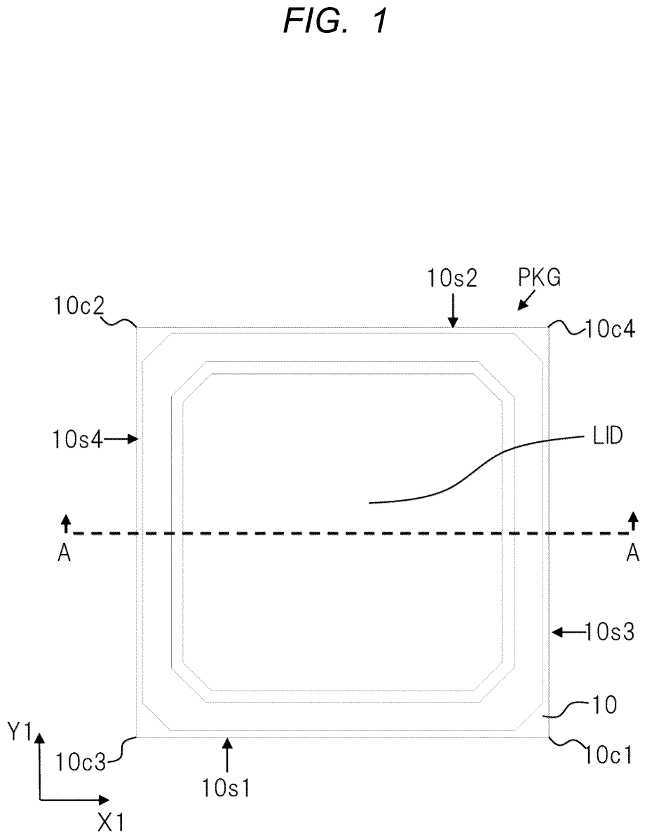

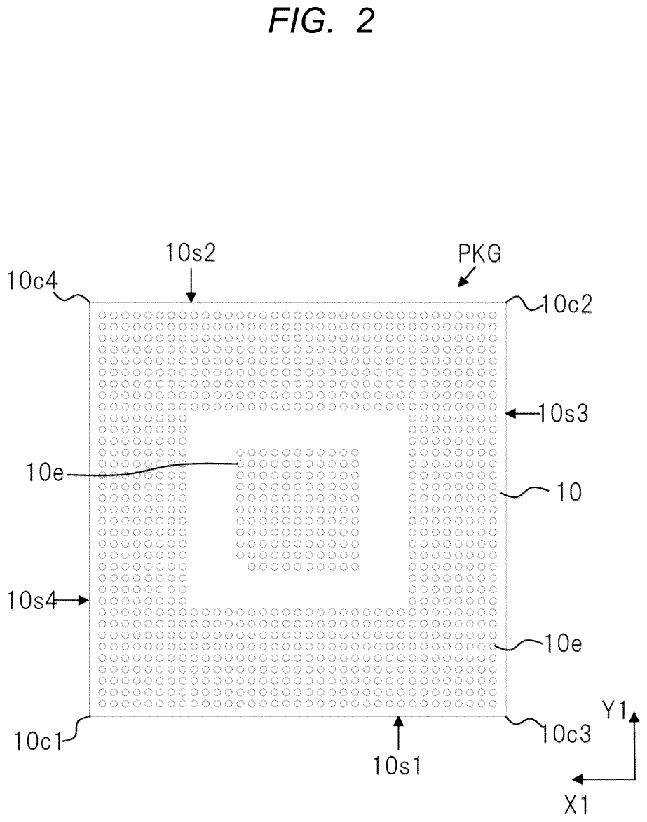

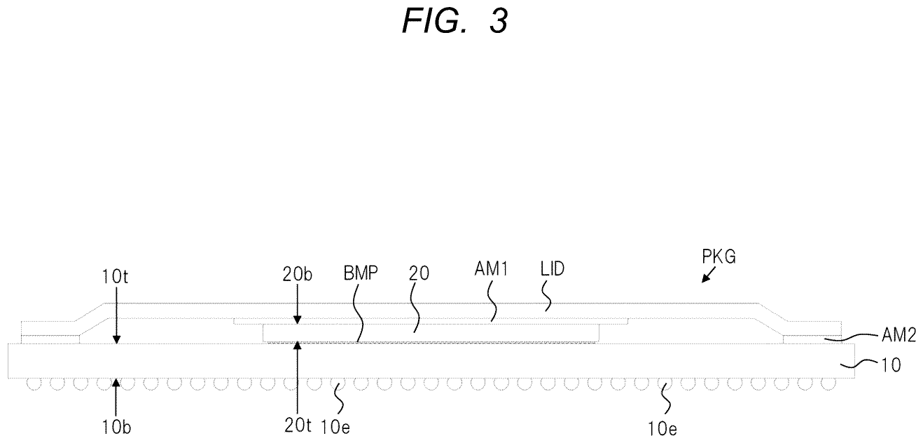

FIG. 1 is an upper surface view of a semiconductor device PKG of the first embodiment. FIG. 2 is a lower surface view of the semiconductor device PKG shown in FIG. 1. FIG. 3 is a cross-sectional view along the line A-A shown in FIG. 1.

As shown in FIG. 1, the semiconductor device PKG according to the first embodiment includes: a wiring substrate 10 of a quadrangular shape having four sides 10s1, 10s2, 10s3, 10s4 and four corners 10c1, 10c2, 10c3, 10c4, and a heat dissipation plate LID arranged to cover the upper surface of this wiring substrate 10. Specifically, as shown in FIG. 1, the wiring substrate 10 includes a side 10s1 extending in a first direction (referred to as “X1” direction in FIG. 1), a side 10s2 facing the side 10s1 and extending in the first direction, a side 10s3 located between these two sides 10s1, 10s2 and extending in a second direction (referred to as “Y1” direction in FIG. 1) perpendicular to the first direction, and a side 10s4 facing the side 10s3 and extending in the second direction. Furthermore, as shown in FIG. 1, the wiring substrate 10 includes a corner 10c1 where the side 10s1 and the side 10s3 intersect, a corner 10c2 where the side 10s2 and the side 10s4 intersect, a corner 10c3 where the side 10s4 and the side 10s1 intersect, and a corner 10c4 where the side 10s3 and the side 10s2 intersect. Although not shown, the wiring substrate 10 corresponds to one of the multiple package areas provided on a single substrate. That is, the wiring substrate 10 is obtained by cutting this single substrate using a dicing blade (rotating cutting blade) or a punch (die). The heat dissipation plate LID is made of, for example, a metal member.

As shown in FIG. 2, on the lower surface of the semiconductor device PKG according to the first embodiment, multiple external connection terminals 10e are provided. As shown in FIG. 2, the multiple external connection terminals 10e are provided along each of the sides 10s1, 10s2, 10s3, 10s4 of the wiring substrate 10 and across multiple rows. In the first embodiment, these external connection terminals 10e are solder balls. Specifically, multiple bump lands (not shown) are provided on the lower surface of the wiring substrate 10, and each solder ball is formed on each bump land.

As shown in FIG. 3, the wiring substrate 10 has an upper surface 10t and a lower surface 10b opposite to this upper surface 10t. Although not shown, multiple bonding fingers are provided on the upper surface 10t of the wiring substrate 10. The multiple bonding fingers (terminals) are electrically connected to multiple bump lands (terminals) provided on the wiring substrate 10 via multiple wirings (not shown). More specifically, a solder resist film (not shown) is formed on the upper surface 10t of the wiring substrate 10, and each bonding finger is exposed within an opening provided in this solder resist film. Similarly, a solder resist film is formed on the lower surface 10b of the wiring substrate 10, and each bump land is exposed within an opening provided in this solder resist film. The wiring substrate 10 according to the first embodiment is, for example, a glass epoxy substrate made by impregnating glass fibers with resin.

Furthermore, as shown in FIG. 3, a semiconductor chip 20 is mounted on the upper surface 10t of the wiring substrate 10. In the first embodiment, the semiconductor chip 20 is mounted on the wiring substrate 10 via a plurality of bump electrodes BMP such that the main surface 20t of the semiconductor chip 20 faces the upper surface 10t of the wiring substrate 10, as shown in FIG. 3. That is, the semiconductor device PKG of the first embodiment is a so-called face down (flip chip) mounting type semiconductor device that electrically connects the semiconductor chip 20 to the wiring substrate 10 via a plurality of bump electrodes BMP. Although not shown, a plurality of electrode pads electrically connected to the semiconductor elements (for example, field-effect transistors) formed in the semiconductor chip 20 are provided on the main surface 20t of the semiconductor chip 20, and in the first embodiment, each bump electrode BMP is pre-formed on each electrode pad.

Furthermore, in the first embodiment, as shown in FIG. 3, a heat dissipation plate LID is arranged on the wiring substrate 10 so as to cover the semiconductor chip 20. Also, as shown in FIG. 3, a part (central portion) of the heat dissipation plate LID is fixed to the back surface 20b of the semiconductor chip 20 via a conductive adhesive material AM1. Moreover, as shown in FIG. 3, another part (peripheral portion) of the heat dissipation plate LID is fixed to the wiring substrate 10 via an insulating adhesive material AM2. It should be noted that a conductive adhesive material may be used as the adhesive material AM2. And another part (peripheral portion) of the heat dissipation plate LID is located around the part (central portion) of the heat dissipation plate LID, as shown in FIG. 1. Furthermore, the heat dissipation plate LID is bent so that another part (peripheral portion) of the heat dissipation plate LID is positioned closer to the wiring substrate 10 than a part (central portion) of the heat dissipation plate LID, as shown in FIG. 3. This allows the thickness of the adhesive material AM2 to be made almost the same as the thickness of the adhesive material AM1. And, if the adhesive material AM2 is the same material as the adhesive material AM1, only one type of adhesive material needs to be prepared.

### Carrier Tape

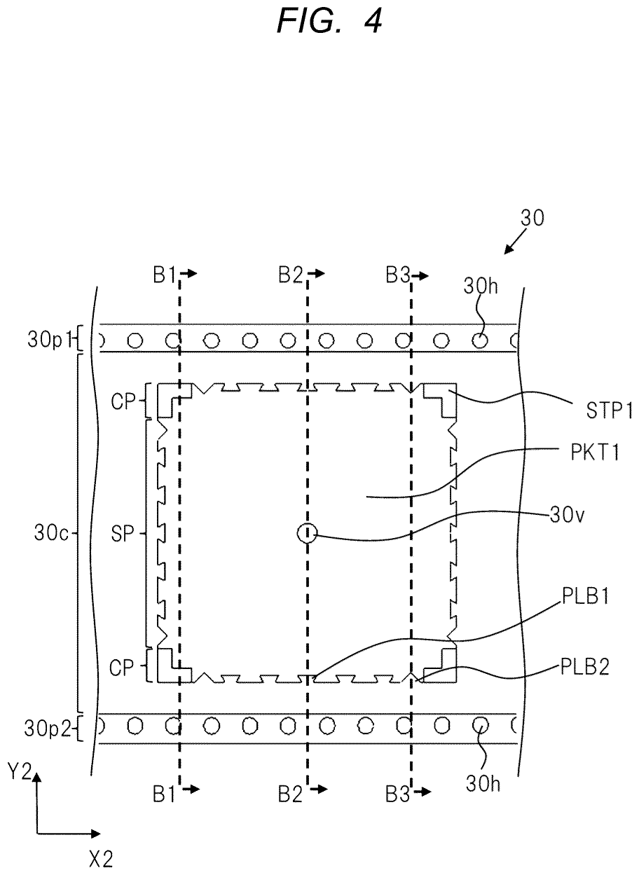

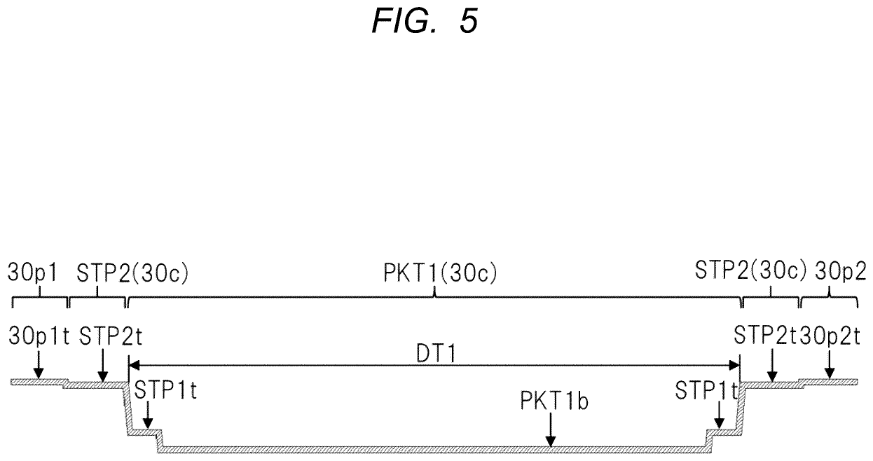

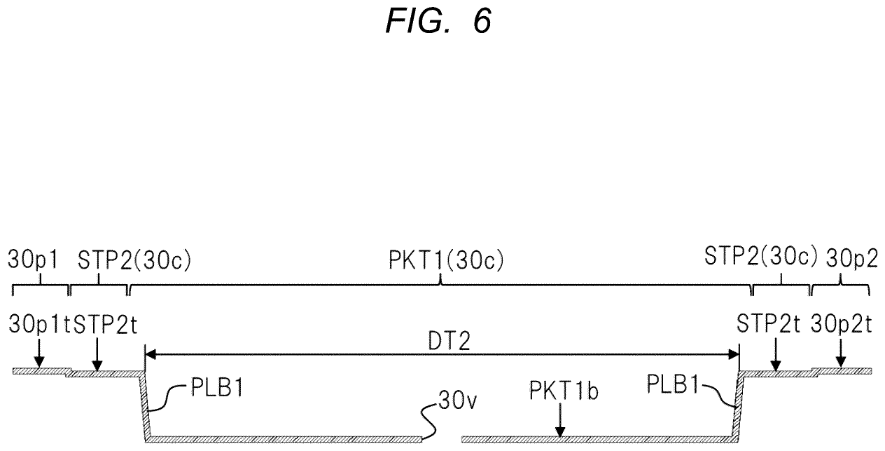

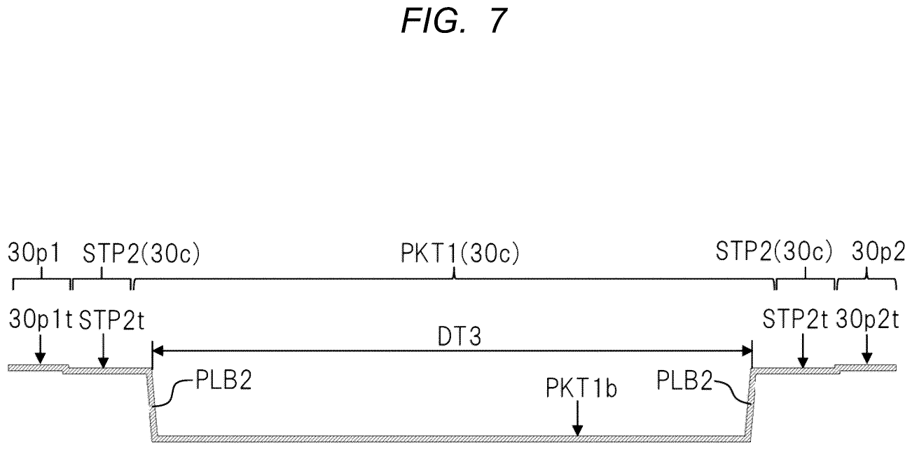

Next, the carrier tape 30 of the first embodiment will be described. FIG. 4 is an enlarged plan view at a portion of the carrier tape of the first embodiment. FIG. 5 is a cross-sectional view taken along the line B1-B1 in FIG. 4. FIG. 6 is a cross-sectional view taken along the line B2-B2 in FIG. 4. FIG. 7 is a cross-sectional view taken along the line B3-B3 in FIG. 4.

As shown in FIG. 4, the carrier tape 30 of the first embodiment includes two peripheral portions 30p1, 30p2 extending in a first direction (referred to as “X2” direction in FIG. 4), and a central portion 30c extending in the first direction, located between these two peripheral portions 30p1, 30p2 in a second direction perpendicular to the first direction (referred to as “Y2” direction in FIG. 4). Furthermore, as shown in FIG. 4, a plurality of through-holes (sprocket holes) 30h are provided in each peripheral portion 30p1, 30p2 of the carrier tape 30. These plurality of through-holes 30h are arranged in the first direction, as shown in FIG. 4. In addition, a plurality of accommodating portions (storage portion, pocket portions) PKT1 is provided in the central portion 30c of the carrier tape 30. A through-hole 30v is provided in the center of each accommodating portion PKT1. Since each accommodating portion PKT1 is formed by embossing the carrier tape 30 using, for example, a mold or air pressure, the carrier tape 30 of the first embodiment is also referred to as an embossed carrier tape (or blister tape). Moreover, in the present embodiment, the shapes of the plurality of accommodating portions PKT are the same as each other. Therefore, when explaining details about the accommodating portion PKT1 in the present embodiment, one accommodating portion PKT1 will be described.

Furthermore, the carrier tape 30 of the first embodiment is made from a resin material mixed with, for example, carbon. Specifically, the carrier tape 30 has a structure in which a layer made of conductive polystyrene or conductive polycarbonate is formed on both surfaces of a substrate (core layer) made of polystyrene resin, ABS resin, or polyethylene terephthalate resin. That is, the carrier tape 30 of the first embodiment has a certain degree of conductivity. This can suppress the charging of the carrier tape 30. As a result, it is possible to suppress a decrease in the reliability of the semiconductor device PKG during the transportation of the carrier tape 30 with the semiconductor device PKG housed in the accommodating portion PKT1.

Next, the planar shape of the accommodating portion PKT1 will be described using FIG. 4. In the present embodiment 1, the accommodating portion PKT1 includes four corner portions CP where a step portion STP1 is formed, and four side portions SP each located between two corner portions CP that are adjacent to each other in either the first direction X2 or the second direction Y2 and where the first protruding portion PLB1 and the second protruding portion PLB2 are formed. The planar shape of each step portion STP1 is L-shaped. Furthermore, the tip portion of the first protruding portion PLB1 protruding towards the inside of the accommodating portion PKT1 from each side portion SP, and the tip portion of the second protruding portion PLB2 protruding towards the inside from each side portion, are different from each other. Specifically, the width of the tip portion of the second protruding portion PLB2 (i.e., the length along the adjacent side portion SP) is smaller than (less than) the width of the tip portion of the first protruding portion PLB1 (i.e., the length along the adjacent side portion SP). That is, in plan view, the tip portion of the second protruding portion PLB2 is more pointed than the tip portion of the first protruding portion PLB1. Moreover, the tip portion of the second protruding portion PLB2 is located more towards the inside of the accommodating portion PKT1 than the tip portion of the first protruding portion PLB1. That is, the protrusion amount of the second protruding portion PLB2 from the side portion SP is larger than (greater than) the protrusion amount of the first protruding portion PLB1 from the side portion SP. Here, the “protrusion amount” of each protruding portion refers to, for example, in the case of a protrusion extending from a side portion SP in the first direction X2 towards the inside of the accommodating portion PKT1, the length in the second direction Y2 from this side portion SP to the tip of the protruding portion. In the present embodiment 1, an example in which five of the first protruding portions PLB1 and two of the second protruding portions PLB2 are provided with each side portion SP is described, but the number of the first protruding portions PLB1 is not limited to this. Furthermore, on each side portion SP, the five of the first protruding portions PLB1 are provided between the two of the second protruding portions PLB2. In other words, the two of the second protruding portions PLB2 are located at both end portions of each side portion SP so as to sandwich the first protruding portions PLB1 therebetween.

Next, the cross-sectional shape of the accommodating portion PKT1 will be described using FIGS. 5 to 7. First, as shown in FIG. 5, the step portion STP1 is provided at each corner portion CP of the accommodating portion PKT1 such that the upper surface STP1t of this step portion STP1 is positioned above the bottom surface PKT1b of the accommodating portion PKT1, and the upper surface STP1t of this step portion STP1 is positioned below each upper surface 30p1t, 30p2t of the peripheral portions 30p1, 30p2. In the present embodiment 1, as shown in FIG. 5, another step portion STP2 is provided between the accommodating portion PKT1 and the peripheral portions 30p1, 30p2. Furthermore, as shown in FIG. 5, this other step portion STP2 is provided between the two peripheral portions 30p1, 30p2 such that the upper surface STP2t of this other step portion STP2 is positioned above the upper surface STP1t of the step portion STP1, and the upper surface STP2t of this other step portion STP2 is positioned below each upper surface 30p1t, 30p2t of the peripheral portions 30p1, 30p2. Also, as shown in FIG. 5, the upper surface STP1t of the step portion STP1, the bottom surface PKT1b of the accommodating portion PKT1, each upper surface 30p1t, 30p2t of the peripheral portions 30p1, 30p2, and the upper surface STP2t of the other step portion STP2 are substantially parallel to each other.

Furthermore, as described above, the cross-sectional view shown in FIG. 6 corresponds to the cross-sectional view along the line B2-B2 shown in FIG. 4. Therefore, although the aforementioned step portion STP1 is not shown in FIG. 6, the first protruding portion PLB1 and the through-hole 30v can be confirmed. Also, the tip surface of the first protruding portion PLB1 (the surface facing the side surface of the wiring substrate 10) protrudes inward of the accommodating portion PKT1 (towards the through-hole 30v side) more than the inner wall surface of the accommodating portion PKT1 (the surface facing the side surface of the wiring substrate 10) (refer to FIGS. 5 and 6 together). That is, as shown in FIGS. 5 and 6, the distance DT2 between the tip surfaces of the two of the first protruding portions PLB1 facing each other in the second direction Y2 is smaller than the distance DT1 between the inner wall surfaces of the two accommodating portions PKT1 facing each other in the second direction Y2.

Furthermore, as described above, the cross-sectional view shown in FIG. 7 corresponds to the cross-sectional view along the line B3-B3 shown in FIG. 4. Therefore, although the aforementioned step portion STP1 is not shown in FIG. 7, the second protruding portion PLB2 can be confirmed. Also, similar to the first protruding portion PLB1, the tip portion of the second protruding portion PLB2 (portion facing side surface of wiring substrate 10) protrudes inward of the accommodating portion PKT1 more than the inner wall surface of the accommodating portion PKT1 (refer to FIGS. 5 and 7 together). That is, as shown in FIGS. 5 and 7, the distance DT3 between the tip portions of the two of the second protruding portions PLB2 facing each other in the second direction Y2 is smaller than the distance DT1 between the inner wall surfaces of the two accommodating portions PKT1 facing each other in the second direction Y2. Furthermore, the tip portion of the second protruding portion PLB2 protrudes inward of the accommodating portions PKT1 more than the tip surface of the first protruding portion PLB1 (refer to FIGS. 6 and 7 together). That is, as shown in FIGS. 6 and 7, the distance DT3 between the tip portions of the two of the second protruding portions PLB2 facing each other in the second direction Y2 is smaller than the distance DT2 between the tip surfaces of the two of the first protruding portions PLB1 facing each other in the second direction Y2.

### Transportation Method of Semiconductor Device

Next, a method of transporting a semiconductor device of the first embodiment will be described. First, prepare the semiconductor device PKG described with reference to FIGS. 1 to 3, and the carrier tape 30 described with reference to FIGS. 4 to 7. It should be noted that the semiconductor device PKG prepared here is, for example, a product (shipment product) that has completed a series of assembly processes (subsequent processes) and has been determined to be a non-defective product by a testing process.

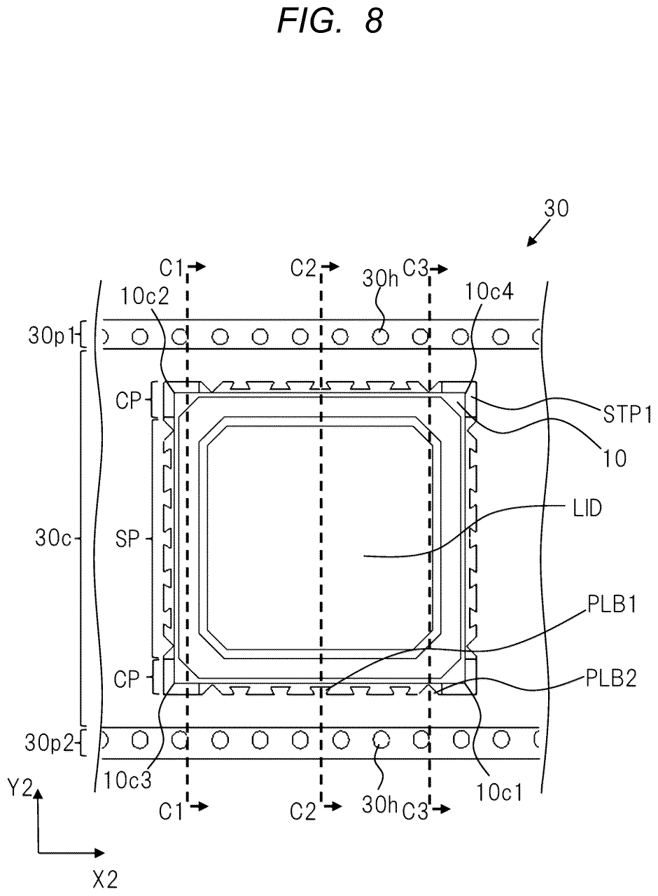

Next, as shown in FIGS. 8 to 11, the semiconductor device PKG is placed (stored) in the accommodating portion (pocket portion) PKT1 of the carrier tape 30. Specifically, the semiconductor device PKG is placed inside the storage section PKT1 so that the lower surface 10b of the wiring substrate 10 faces the bottom surface PKT1b of the accommodating portion PKT1. At this time, the air inside the accommodating portion PKT1 is suctioned through the through-hole 30v formed in the bottom surface PKT1b of the accommodating portion PKT1. This allows the semiconductor device PKG to be easily placed inside the accommodating portion PKT1. Furthermore, as shown in FIG. 8, the semiconductor device PKG is placed inside the accommodating portion PKT1 so that each corner 10c1, 10c2, 10c3, 10c4 of the wiring substrate 10 is located at each corner portion CP of the accommodating portion PKT1. It should be noted that, as shown in FIG. 8, at each corner portion CP of the accommodating portion PKT1, the wiring substrate 10 does not contact the carrier tape 30.

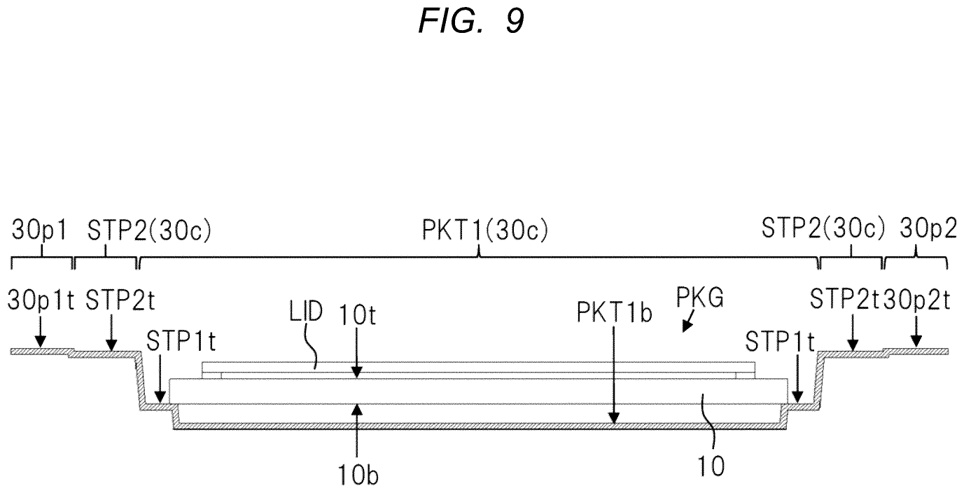

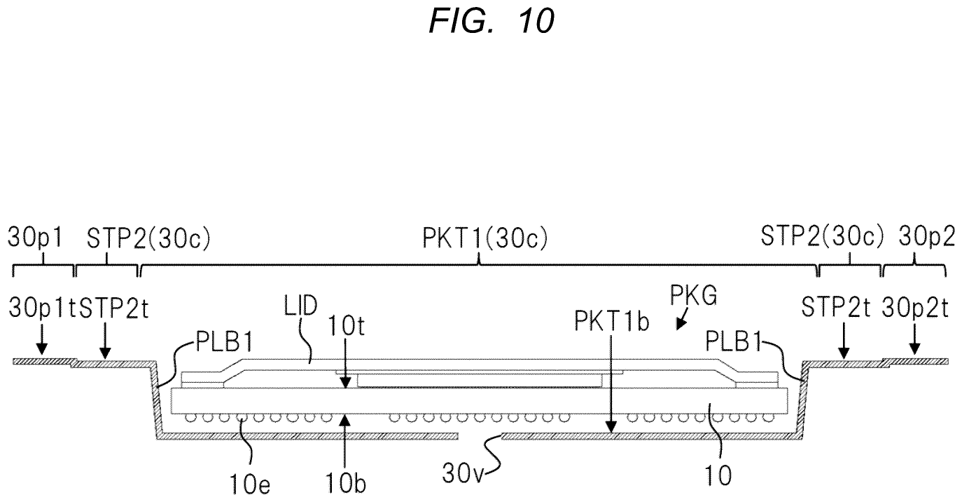

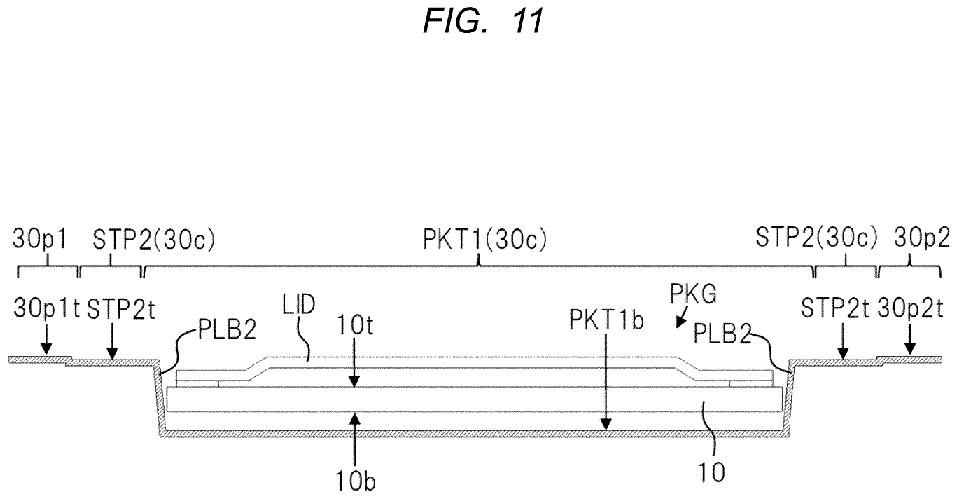

The lower surface 10b of the peripheral portion of the wiring substrate 10 of the semiconductor device PKG placed in the accommodating portion PKT1 is, at the position along the line C1-C1 shown in FIG. 8, in contact with the upper surface STP1t of the step portion STP1 of the carrier tape 30 (refer to FIG. 9). It should be noted that the “peripheral portion” of the wiring substrate 10 mentioned here refers to the area located outside the outermost row of multiple external connection terminals 10e shown in FIG. 2. Furthermore, as shown in FIG. 9, the lower surface 10b of the wiring substrate 10 and the upper surface STP1t of the step portion STP1 are almost parallel to each other. Also, at the position along the line C2-C2 shown in FIG. 8, the wiring substrate 10 (namely, semiconductor device PKG) is spaced apart from the first protruding portions PLB1 (refer to FIG. 10). Similarly, the multiple external connection terminals 10e are also separated from the bottom surface PKT1b of the accommodating portion PKT1 (refer to FIG. 10). That is, at the position along the line C2-C2 shown in FIG. 8, the semiconductor device PKG does not contact the carrier tape 30. On the other hand, at the position along the line C3-C3 shown in FIG. 8, the wiring substrate 10 is in contact with the second protruding portion PLB2 (refer to FIGS. 8 and 11). That is, the distance between the second protruding portion PLB2 and the wiring substrate 10 is smaller than the distance between the first protruding portion PLB1 and the wiring substrate 10. Here, as shown in FIGS. 10 and 11, the semiconductor device PKG is placed inside the accommodating portion PKT1 so that the surface (upper surface) of the heat dissipation plate LID is located above the upper surface STP2t of another step portion STP2. Furthermore, in the first embodiment, although two of the second protruding portions PLB2 are provided on each side portion SP of the accommodating portion PKT1, it is not necessary for all (in this case, a total of eight) of the second protrusions PLB2 to be in contact with the wiring substrate 10 when the semiconductor device PKG is placed inside the accommodating portions PKT1.

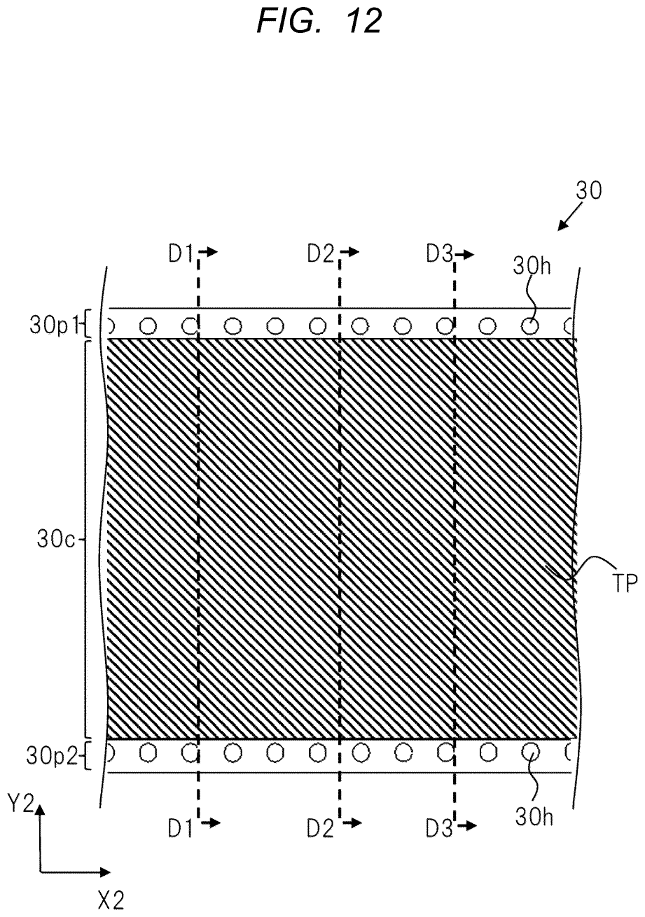

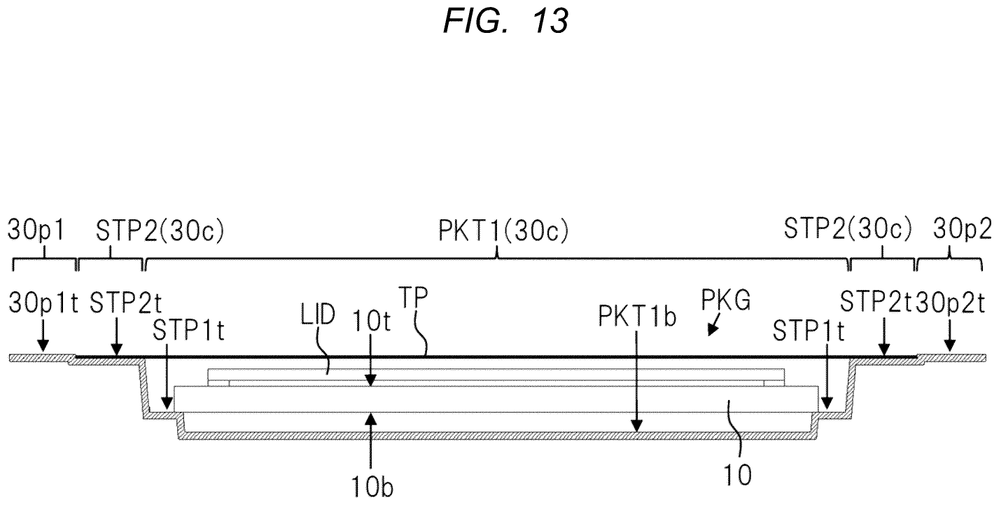

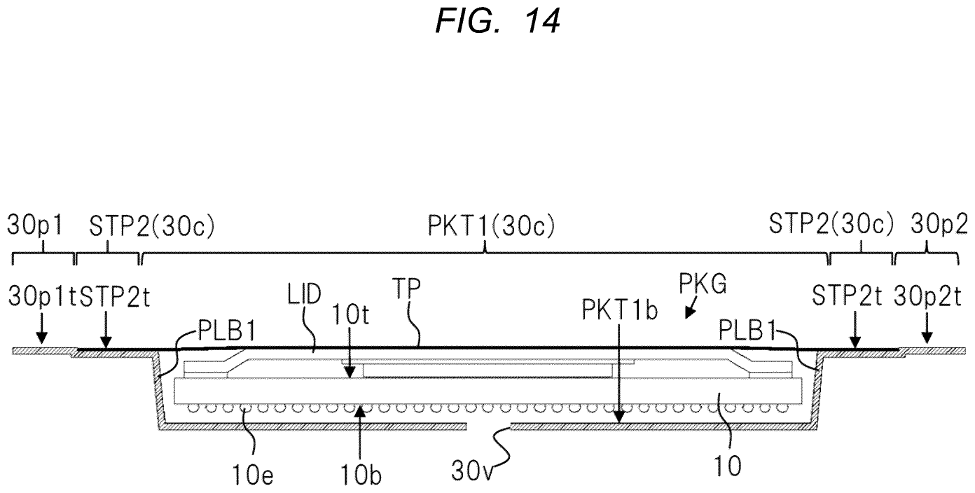

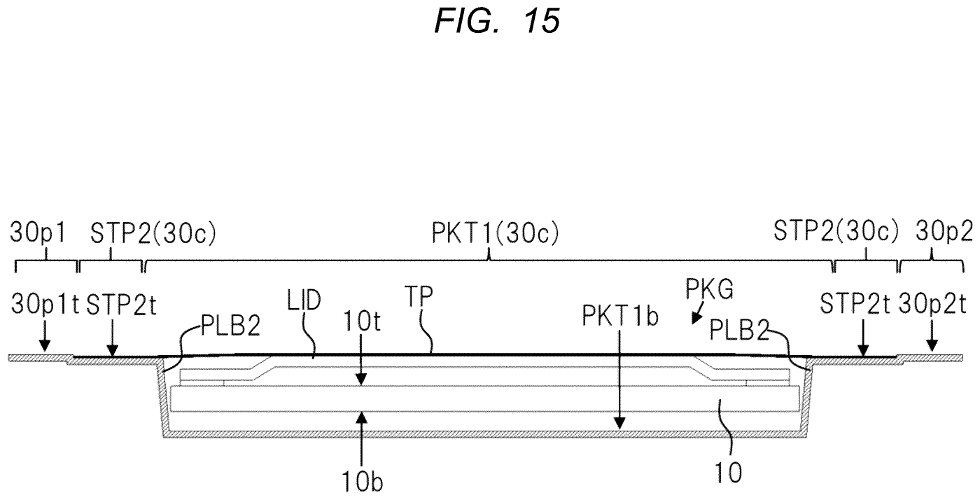

Next, as shown in FIGS. 12 to 15, a cover tape TP is attached to the carrier tape 30 so as to cover the semiconductor device PKG arranged (placed) in the accommodating portion PKT1. Specifically, as shown in FIG. 12, the cover tape TP is attached to the carrier tape 30 along the central portion 30c extending in the first direction X2 between two peripheral portions 30p1, 30p2. At this time, at the position of the D1-D1 line shown in FIG. 12, the cover tape TP is spaced apart from the semiconductor device PKG (refer to FIG. 13). On the other hand, at the positions of the D2-D2 line and the D3-D3 line shown in FIG. 12, the cover tape TP is in contact with the surface (upper surface) of the heat dissipation plate LID (refer to FIGS. 14 and 15). The cover tape TP used in the first embodiment is made of a stretchable material such as polyethylene resin or polyethylene terephthalate resin.

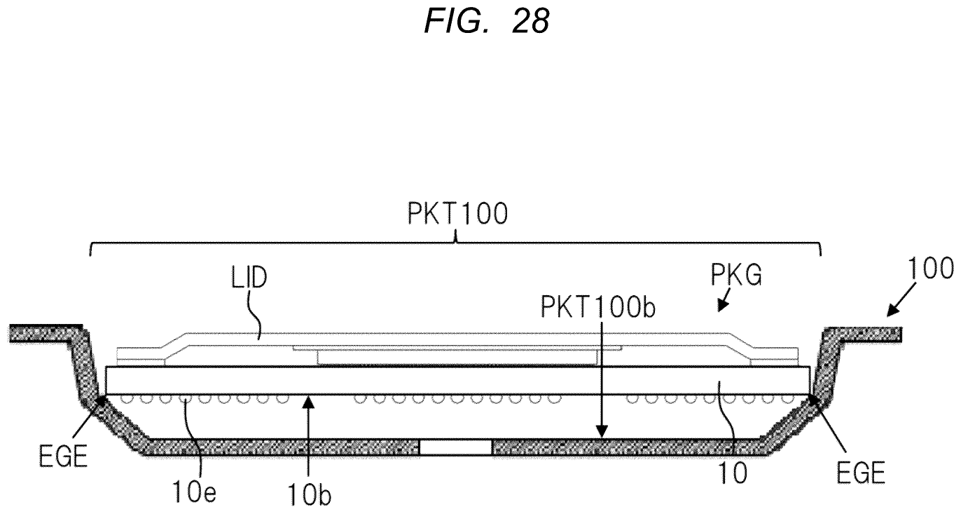

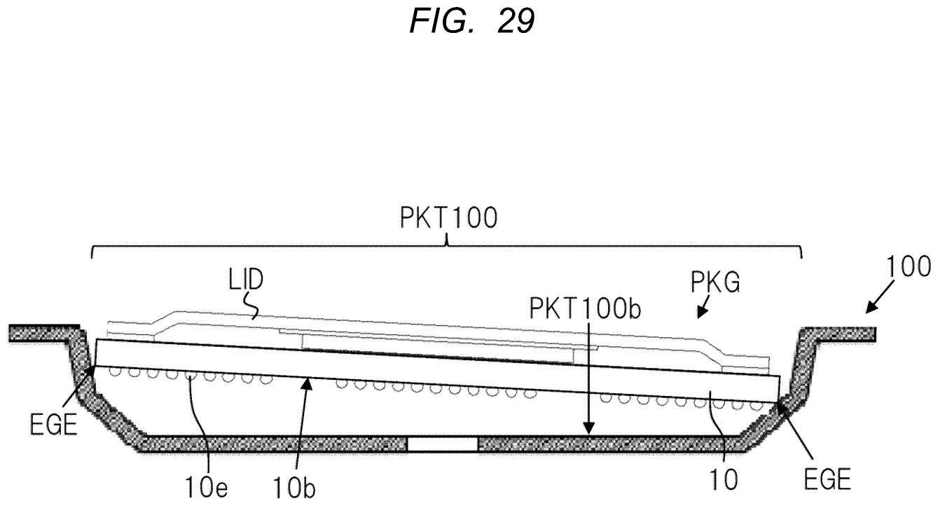

Here, the examined example of the carrier tape 100, which was studied by the present inventors, will be described. FIG. 28 is a cross-sectional view showing the state in which the semiconductor device PKG is housed in the accommodating portions PKT100 of the carrier tape 100 of the examined example. As shown in FIG. 28, the inner wall surface of the accommodating portion PKT100 of the carrier tape 100 of the examined example is inclined in two stages with respect to the bottom surface PKT100b of the accommodating portion PKT100, and at least the step portion STP1, the first protruding portion PLB1, and the second protruding portion PLB2 as in the first embodiment are not provided within the accommodating portion PKT100. Therefore, when the semiconductor device PKG is placed within the accommodating portion PKT100, as shown in FIG. 28, the edges (namely, each side 10s1, 10s2, 10s3, 10s4) EGE of the lower surface 10b of the wiring substrate 10 are in contact with this inner wall surface (tapered surface). According to the study by the present inventors, in the case of the accommodating portion PKT100, because the structure does not support the lower surface 10b of the wiring substrate 10 on the upper surface STP1t of the step portion STP1 as in the first embodiment, it was found that the semiconductor device PKG is prone to tilting within the accommodating portion PKT100 due to vibrations and impacts that occur during the transportation of the carrier tape 100 (refer to FIG. 29). As a result, it was found that the inner wall surface of the accommodating portion PKT100 is scraped off by the edges EGE of the wiring substrate 10. A part of the scraped-off carrier tape 100 becomes foreign matter and scatters within the housing section, potentially adhering across several external connection terminals 10e of the semiconductor device PKG. Furthermore, if the carrier tape is conductive, a part of the carrier tape adhering across several external connection terminals 10e of the semiconductor device PKG may result in a defective product. As a countermeasure, the present inventors also considered using a carrier tape that does not have conductivity. However, even if an insulating carrier tape is used, if a part of the carrier tape becomes foreign matter and scatters within the housing section, it may adhere to the external connection terminals 10e of the semiconductor device PKG. And if foreign matter adheres to the external connection terminals 10e, even if the foreign matter is insulating, it may cause a mounting defect when, for example, mounting this semiconductor device PKG on a mounting substrate.

In contrast, in the case of the carrier tape 30 of the present embodiment 1, as shown in FIG. 9, instead of the edge EGE of the wiring substrate 10, the lower surface 10b of the wiring substrate 10 is supported by the step portions STP1 wiring provided at each corner CP of the accommodating portion PKT1. Therefore, it is possible to suppress the movement of the semiconductor device PKG within the accommodating portion PKT1 due to vibrations or shocks occurring during the transport of the carrier tape 30, or due to the self-weight of the semiconductor device PKG.

Moreover, in the case of the carrier tape 30 of the first embodiment, as shown in FIGS. 9 and 10, the wiring substrate 10 is supported by step portions STP1 provided at each corner portion CP of the accommodating portion PKT1 so that multiple external connection terminals 10e do not contact the bottom surface PKT1b of the accommodating portion PKT1. Here, the planar shape of the step portion STP1 is an L-shape along two adjacent sides of the four sides of the wiring substrate, which is square, as shown in FIG. 4. Therefore, when the semiconductor device PKG is placed within the accommodating portion PKT1, the lower surface 10b of the peripheral portion of the wiring substrate 10 contacts the step portion STP1, but the external connection terminals 10e do not contact this step portion STP1. As a result, it is possible to suppress the deformation of the external connection terminals 10e due to the self-weight of the semiconductor device PKG.

Moreover, in the case of the carrier tape 30 of the first embodiment, during the transport of the carrier tape 30, the lower surface 10b of the wiring substrate 10 is supported by the step portion STP1, while the side surface of the wiring substrate 10 is supported by the second protruding portion PLB2 of the carrier tape. Specifically, during the transport of the carrier tape 30, the tip portion of the first protruding portion PLB1, which is wider than the tip portion of the second protruding portion PLB2, does not contact the wiring substrate 10. That is, in the case of the carrier tape 30 of the first embodiment, compared to the case using the examined example of the carrier tape 100, the total area of the carrier tape contacting the semiconductor device PKG is smaller. Therefore, it is possible to reduce the amount of foreign matter (part of carrier tape that are shaved off) generated due to vibrations and shocks occurring during the transport of the carrier tape 30, or due to the self-weight of the semiconductor device PKG.

Moreover, in the case of the carrier tape 30 of the first embodiment, two of the second protruding portions PLB2 are provided at both end portions of each side portion SP of the accommodating portion PKT1. Therefore, it is possible to suppress the rotation of the semiconductor device PKG within the accommodating portion PKT1 due to vibrations and shocks occurring during the transport of the carrier tape 30, and the contact of the side surface of the wiring substrate 10 with the inner wall surface of the accommodating portion PKT1.

Furthermore, in the case of the carrier tape 30 of the first embodiment, as described above, at the stage of attaching the cover tape TP to the carrier tape 30, the semiconductor device PKG is placed in the accommodating portion PKT1 so that the surface (upper surface) of the heat dissipation plate LID is positioned above the upper surface STP2t of another step portion STP2. Therefore, as shown in FIGS. 14 and 15, when the cover tape TP is attached to the carrier tape 30, the cover tape TP deforms by the amount the semiconductor device PKG protrudes outward from the accommodating portion PKT1. That is, a force pressing the semiconductor device PKG towards the bottom surface PKT1b of the accommodating portion PKT1 acts. This allows for more reliable suppression of the movement of the semiconductor device PKG within the accommodating portion PKT1 even if vibrations and shocks occur during the transport of the carrier tape 30. As a result, it is possible to further reduce the amount of foreign matter generated.

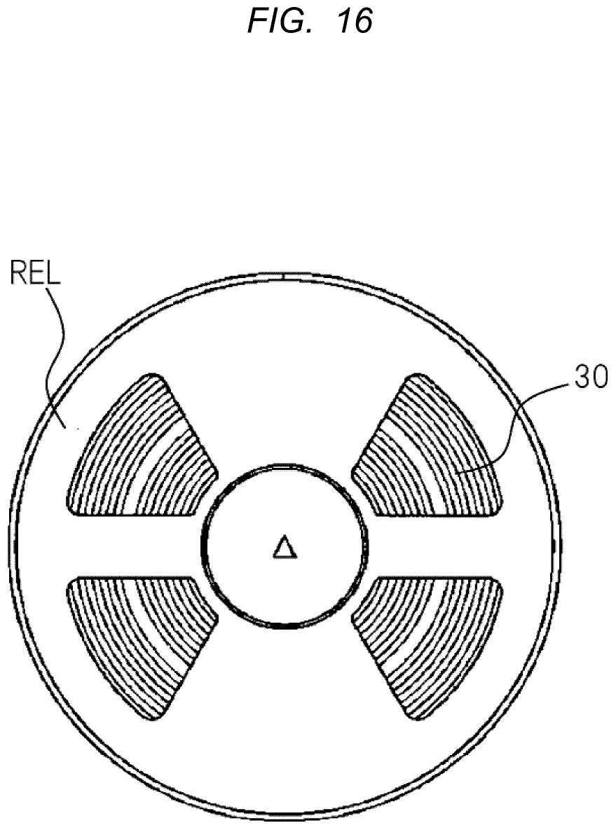

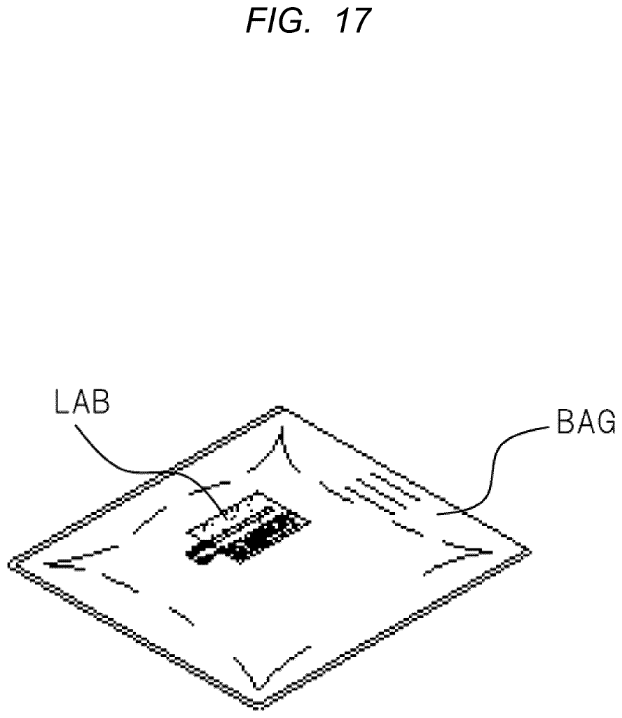

Next, as shown in FIG. 16, a carrier tape 30 with a cover tape TP attached thereto is wound onto a reel REL. It should be noted that the length of the carrier tape 30 that can be wound depends on the size of the reel REL used. Then, as shown in FIG. 17, the reel REL with the wound carrier tape 30 is packaged in a moisture-proof bag BAG. It should be noted that after a label LAB, which includes the product name and model number, for example, is affixed to the surface of the moisture-proof bag BAG made of aluminum, the moisture-proof bag BAG with the reel REL packaged therein is transported (or shipped). At the destination, guide pins (not shown) are inserted into through-holes 30h provided at each peripheral portion 30p1, 30p2 of the carrier tape 30 to feed the carrier tape 30 from the reel REL, and then semiconductor devices PKG are removed from each accommodating portion PKT1.

### First Modified Example

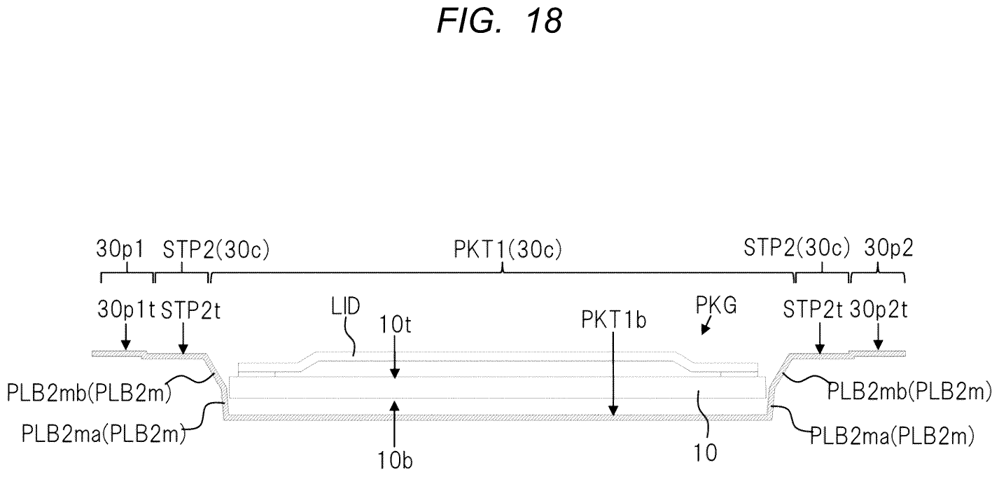

Next, a modified example of the first embodiment will be explained using FIG. 18. First, FIG. 18 corresponds to the position of the line C3-C3 shown in FIG. 8 in the carrier tape 30 of the first embodiment, and the difference from FIG. 11 is in the shape of the second protruding portion PLB2. Specifically, as shown in FIG. 18, the second protruding portion PLB2m of this first modified example has a first portion PLB2ma that connects to the bottom surface PKT1b of the accommodating portion PKT1 and a second portion PLB2mb that connects to this first portion PLB2ma, between the bottom surface PKT1b of the accommodating portion PKT1 and another step portion STP2. Also, as shown in FIG. 18, the slope from the bottom surface PKT1b of the accommodating portion PKT1 to the inner wall surface of the second portion PLB2mb is greater than the slope from the bottom surface PKT1b of the accommodating portion PKT1 to the inner wall surface of the first portion PLB2ma. In other words, the inclination of the inner wall surface of the first portion PLB2ma relative to the bottom surface PKT1b of the accommodating portion PKT1 is smaller than the inclination of the inner wall surface of the second portion PLB2mb relative to the bottom surface PKT1b of the accommodating portion PKT1. Furthermore, as shown in FIG. 18, the point where the first portion PLB2ma and the second portion PLB2mb intersect with each other (i.e., bending point of second protruding portions PLB2m) is positioned between the upper surface 10t and the lower surface 10b of the wiring board 10, among the semiconductor devices PKG accommodated in the accommodating portion PKT1. That is, the second protruding portions PLB2 of the first embodiment had a cross-sectional shape that contacts a wide range of the side surface of the wiring board 10 in the thickness direction of this wiring board 10. In contrast, because the second protruding portion PLB2m of this first modified example is inclined in two stages as shown in FIG. 18, it is possible to reduce the area (length) in which this second protruding portion PLB2m contacts the side surface of the wiring board 10 in the thickness direction. As a result, it is possible to further reduce the amount of foreign matter generated.

### Second Embodiment

Next, the second embodiment will be explained. It should be noted that the difference between this second embodiment and the first embodiment mentioned above lies in the shape (structure) of the storage section of the carrier tape, and other parts are the same as those explained in the first embodiment. Therefore, in this second embodiment, mainly the differences from the first embodiment will be explained.

### Carrier Tape

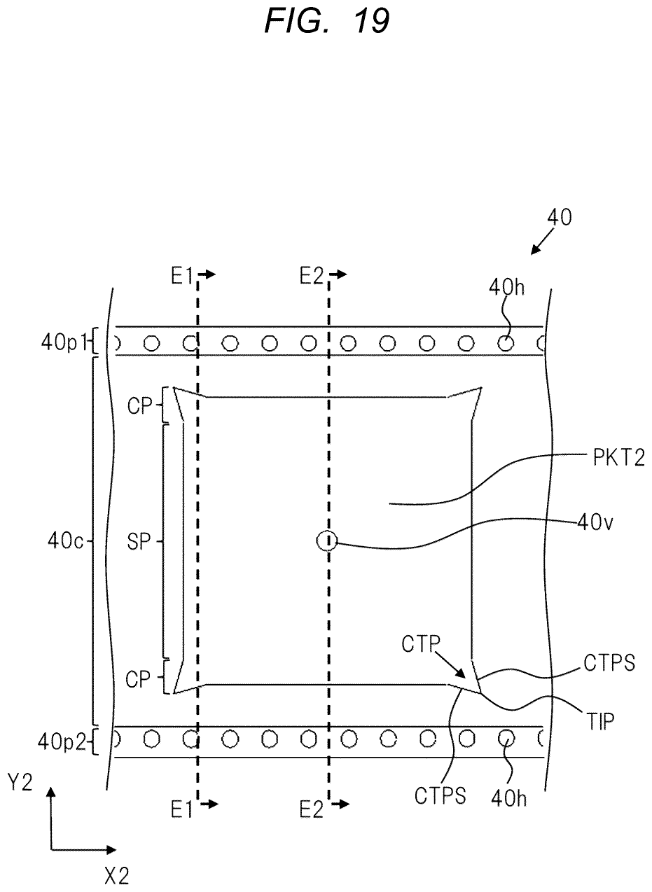

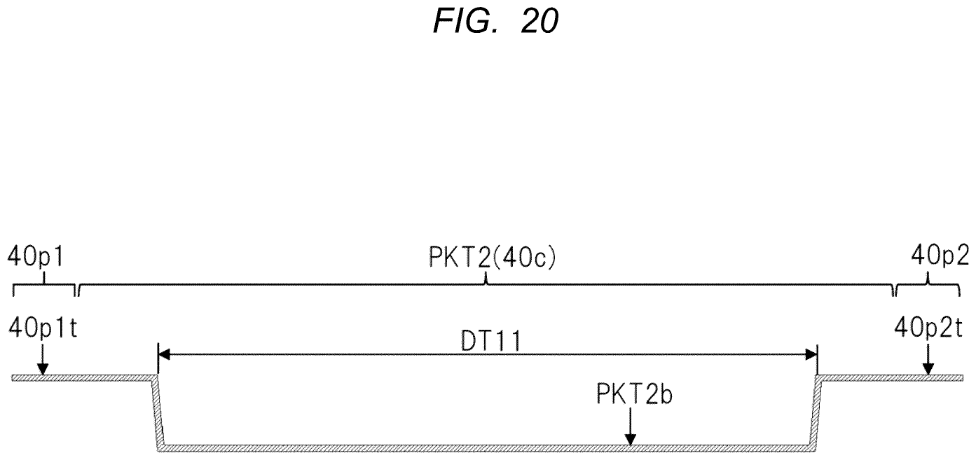

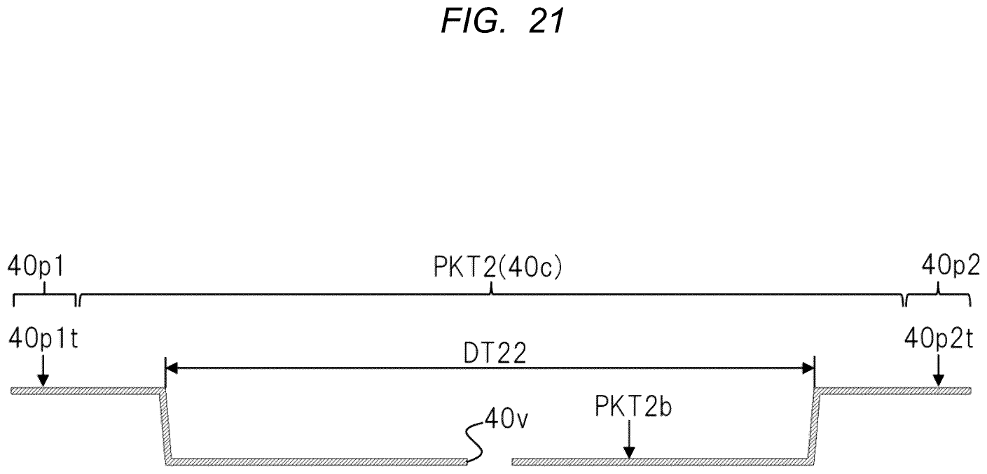

FIG. 19 is an enlarged plan view at a portion of the carrier tape of the second embodiment. FIG. 20 is a cross-sectional view along the line E1-E1 shown in FIG. 19. FIG. 21 is a cross-sectional view along the line E2-E2 shown in FIG. 19. It should be noted that the position of the line E1-E1 shown in FIG. 19 corresponds to the position of the line B1-B1 shown in FIG. 4. Also, the position of the line E2-E2 shown in FIG. 19 corresponds to the position of the line B2-B2 shown in FIG. 4.

As shown in FIG. 19, the accommodating portion PKT2 of the second embodiment includes four corner portions CP each having a notch portion CTP formed therein, and four side portions SP each located between two corner portions CP adjacent to each other in either a first direction X2 or a second direction Y2. Furthermore, the planar shape of the two sides CTPS of each notch portion CTP draws an arc so as to curve from the adjacent side portions SP to the tip (apex) TIP of the notch portion CTP without having a bending point therebetween. That is, the accommodating portion PKT2 does not have the bending point between the side portion SP (more specifically, boundary between each side portion SP and corner portion CP) and the tip TIP of the notch portion CTP provided in the corner portion CP adjacent to that side portion SP. Moreover, the side portions SP do not have the protruding portions PLB1, PLB2 as described in the first embodiment. That is, the planar shape of each side portion SP is a straight line extending in the first direction X2 or the second direction Y2.

Next, the cross-sectional shape of the accommodating portion PKT2 will be described using FIGS. 20 and 21. First, as shown in FIG. 20, since the carrier tape 40 of the second embodiment does not have the step portions STP1, STP2 as in the first embodiment, the cross-sectional shape along the line E1-E1 shown in FIG. 19 is almost the same as the cross-sectional shape along the line E2-E2 shown in FIG. 19. However, as mentioned above, each corner portion CP of the accommodating portion PKT2 of the second embodiment is provided with a notch portion CTP. Therefore, as shown in FIGS. 20 and 21, the distance DT22 between two side portions SP facing each other in the second direction Y2 is smaller than the distance DT11 between the inner wall surfaces of two notch portions CTP facing each other in the second direction Y2. Moreover, this distance DT11 increases towards the tip (apex) TIP of the notch portion CTP.

### Transporting Method of Semiconductor Device

Next, a method of transporting a semiconductor device of the second embodiment will be described. First, a semiconductor device PKG as described using FIGS. 1 to 3, and a carrier tape 40 as described using FIGS. 19 to 21, are prepared.

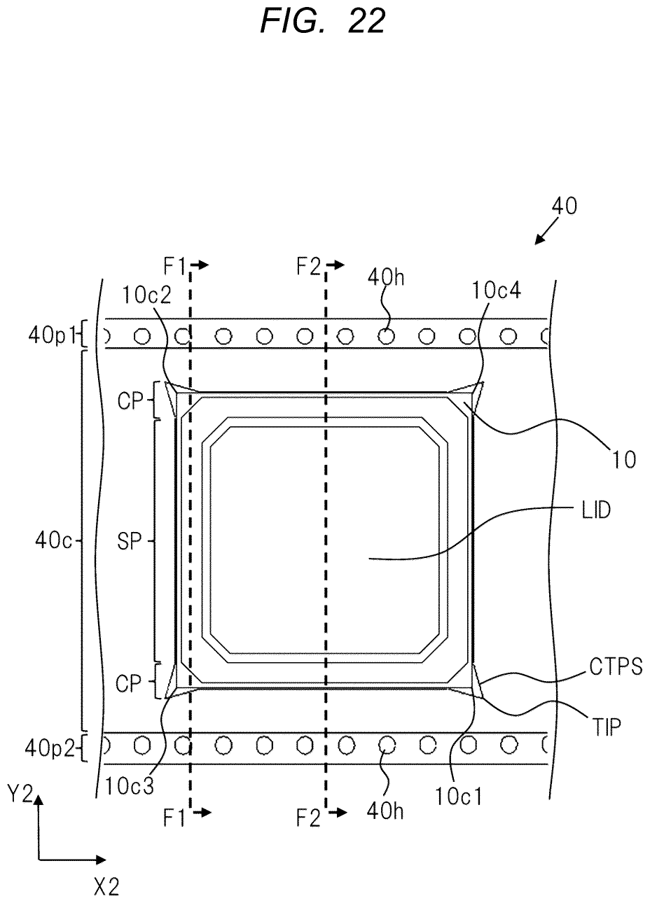

Next, as shown in FIGS. 22 to 24, a semiconductor device PKG is placed (stored) in the accommodating portion (storage portion, pocket portion) PKT2 of the carrier tape 40. Specifically, the semiconductor device PKG is placed within the accommodating portion PKT2 so that the lower surface 10b of the wiring substrate 10 faces the bottom surface PKT2b of the accommodating portion PKT2. Moreover, as shown in FIG. 22, the semiconductor device PKG is placed in the accommodating portion PKT2 such that each corner 10c1, 10c2, 10c3, 10c4 of the wiring substrate 10 is located at each corner portion CP of the accommodating portion PKT2. At this time, since each corner 10c1, 10c2, 10c3, 10c4 of the wiring substrate 10 is located within each notch portion CTP, as shown in FIG. 22, the wiring substrate 10 does not contact the carrier tape 40 at each corner portion CP of the accommodating portion PKT2, similar to the first embodiment.

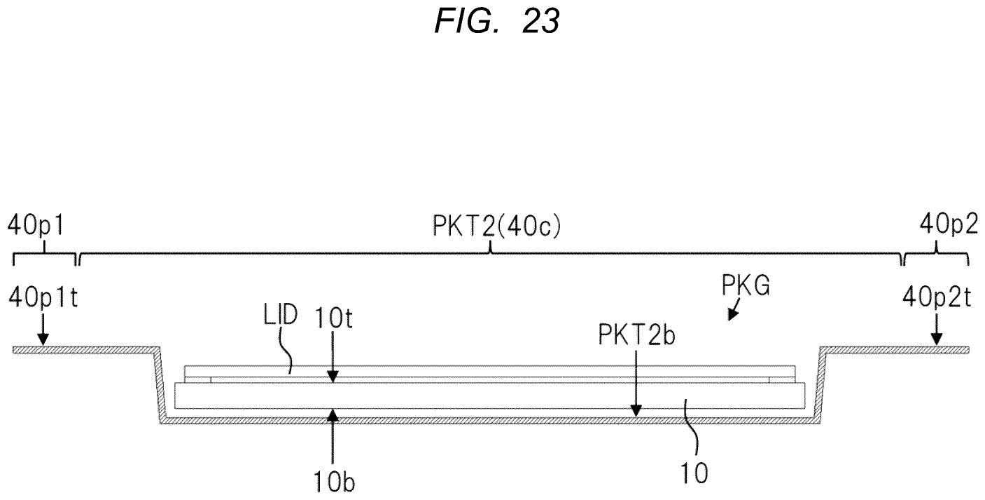

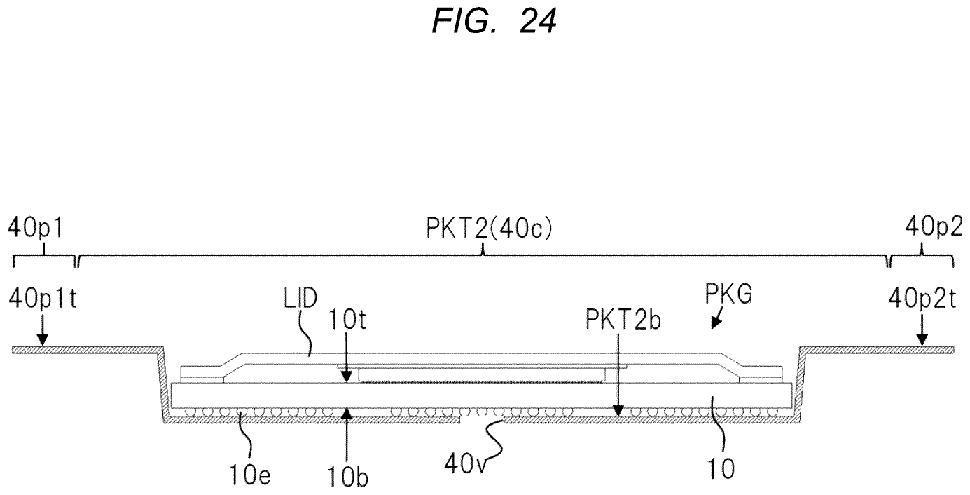

The semiconductor device PKG (namely, peripheral portion of wiring substrate 10) placed in the accommodating portion PKT2 and including the wiring substrate 10 and the heat dissipation plate LID is not in contact with the carrier tape 40 at the position along the line F1-F1 (refer to FIG. 23). On the other hand, at the position on the line F2-F2 shown in FIG. 22, the wiring substrate 10 is in contact with the inner wall surface of the accommodating portion PKT2 of the carrier tape 40 (see FIG. 24). Specifically, as shown in FIG. 22, the wiring substrate 10 is in contact with the carrier tape 40 (that is, the inner wall surface of the accommodating portion PKT2) over the entire region of each side portion SP of the accommodating portion PKT2. This is because, in the second embodiment, each side portion SP adjacent to each side 10s1, 10s2, 10s3, 10s4 of the wiring substrate 10 does not have the protrusions PLB1, PLB2 as in the first embodiment. Therefore, in plain view, the width (length) of the portion of the carrier tape that is in contact with the wiring substrate 10 is greater than the width (length) of the tips of the protrusions PLB1, PLB2 that are in contact with the wiring substrate 10. As a result, compared to the carrier tape 30 of the first embodiment, the area of contact between the carrier tape 40 and the semiconductor device PKG increases, while the impact per unit area generated by the contact between the carrier tape 40 and the semiconductor device PKG decreases. This allows for a reduction in the amount of foreign matter (parts of the carrier tape that are shaved off) generated by vibrations and impacts during the transport of the carrier tape 40 or by the weight of the semiconductor device PKG.

Furthermore, as mentioned above, the corner portions CP of the accommodating portion PKT2 in the second embodiment are not provided with the step portion STP1 as in the first embodiment (refer to FIG. 19). This is because, as shown in FIG. 19, each notch portion CTP is provided such that the distance between the two sides CTPS forming the notch portion CTP gradually decreases towards the tip (apex) TIP of the notch portion CTP. That is, the processing of each corner portion CP in the second embodiment is more difficult compared to the first embodiment. Therefore, as shown in FIG. 24, the external connection terminals 10e of the semiconductor device PKG placed inside the accommodating portion PKT2 are in contact with the bottom surface PKT2b of the accommodating portion PKT2.

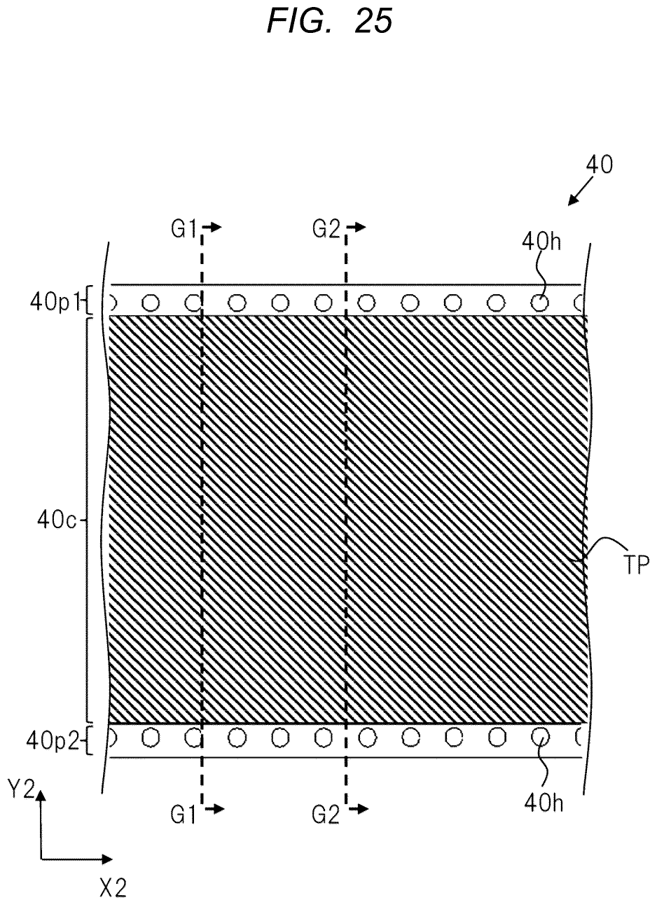

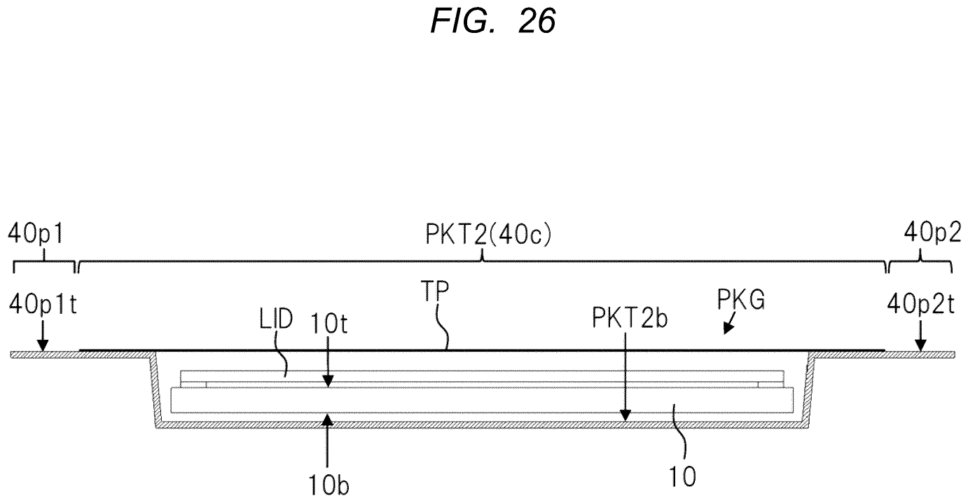

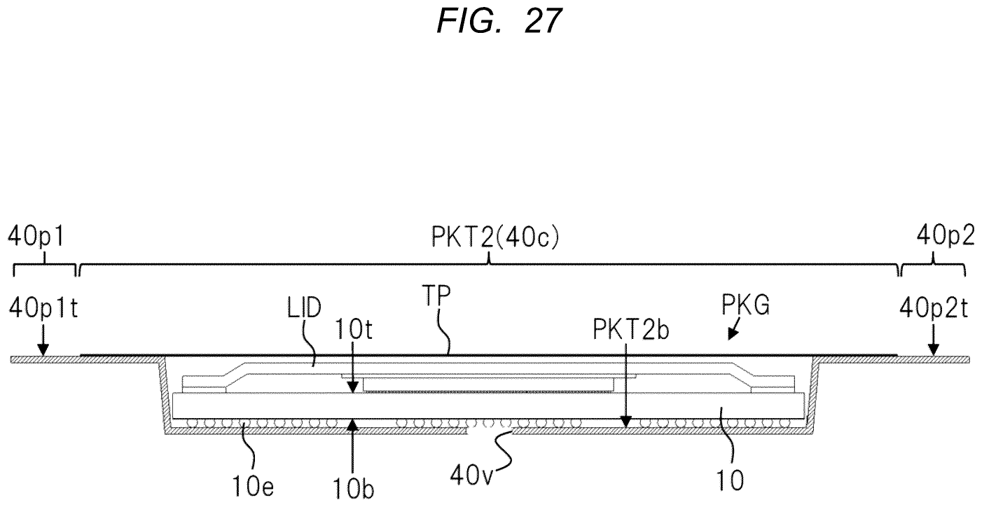

Next, as shown in FIGS. 25 to 27, a cover tape TP is attached to the carrier tape 40 so as to cover the semiconductor device PKG arranged (placed) in the accommodating portion PKT2. Specifically, as shown in FIG. 25, the cover tape TP is attached to the carrier tape 40 along the central portion 40c extending in the first direction X2 between two peripheral portions 40p1, 40p2. At this time, at the position on the line G1-G1 shown in FIG. 25, the cover tape TP is spaced apart from the semiconductor device PKG (refer to FIG. 26). Also, at the position on the line G2-G2 shown in FIG. 25, the cover tape TP is spaced apart from the semiconductor device PKG (refer to FIG. 27). This is because the accommodating portion PKT2 of the second embodiment does not have the step portion STP2 described in the first embodiment.

As described above, the invention made by the present inventor has been specifically described based on the embodiment, but the present invention is not limited to the above embodiment, and it is needless to say that various modifications can be made without departing from the gist thereof.

For example, in the embodiments described above, as an example of the semiconductor device PKG, a semiconductor device of the so-called face-down (flip-chip) mounting type, which electrically connects the semiconductor chip 20 to the wiring substrate 10 via multiple bump electrodes BMP, has been described, but it may also be a semiconductor device of the so-called face-up mounting type using multiple bonding wires. That is, it may be a semiconductor device PKG that does not have a heat dissipation plate LID. On the other hand, in the case of the semiconductor device PKG of the embodiments described above, since it also includes a heat dissipation plate LID, the weight of the semiconductor device 10 is greater than the weight of the semiconductor device of the face-up mounting type. Therefore, the aforementioned foreign objects are also significant when transporting the semiconductor device PKG of the present embodiment.

Moreover, for example, in the embodiments described above, as shown in FIG. 3, an example where the heat dissipation plate LID is bent so that another part (peripheral portion) of the heat dissipation plate LID is located closer to the wiring substrate 10 than a part (central portion) of the heat dissipation plate LID has been described, but a heat dissipation plate without bending processing may be used. However, when using a heat dissipation plate without bending processing, it is necessary to increase the thickness of the adhesive material AM2.

Furthermore, for example, in the embodiments described above, it has been described that the carrier tape has a certain degree of conductivity, but an insulating carrier tape may be used. However, even if an insulating carrier tape is used, if a part of the carrier tape becomes a foreign object and scatters inside the housing section, it may adhere to the external connection terminals 10e of the semiconductor device PKG. And if foreign objects adhere to the external connection terminals 10e, even if the foreign objects are insulating, there is a risk of causing mounting defects when, for example, mounting this semiconductor device PKG on a mounting substrate. On the other hand, with the structure of the accommodating portions PKT1, PKT2 of the embodiments described above, since it is possible to suppress the scattering of a part of the carrier tape as foreign objects, the accommodating portions PKT1, PKT2 of the embodiments described above are effective even for insulating carrier tapes.

Furthermore, for example, in the first embodiment, it was explained that another step portion STP2 is provided between the accommodating portion PKT1 and each peripheral portion 30p1, 30p2, but this another step portion STP2 may not be provided. However, in order to prevent the semiconductor device from moving as much as possible during the transportation of the carrier tape 30, it is preferable to provide this another step portion STP2 as in the first embodiment. Similarly, in the second embodiment, it was explained that another step portion STP2 is not provided between the accommodating portion PKT2 and each peripheral portion 40p1, 40p2, but from the viewpoint of preventing the semiconductor device PKG from moving as much as possible during the transportation of the carrier tape 40, it is preferable to provide another step portion STP2 in the carrier tape 40 of the second embodiment, similar to the first embodiment. By doing so, it is possible to press the semiconductor device PKG, which is placed in the accommodating portion PKT2 of the carrier tape 40, towards the bottom surface PKT2b of the accommodating portion PKT2, and more reliably prevent the semiconductor device PKG from moving within the accommodating portion PKT2 during the transportation of the carrier tape 40. However, from the viewpoint of suppressing deformation of the external connection terminal 10e as much as possible, in the carrier tape 40 of the second embodiment, which does not have a step portion STP1 like the first embodiment, it is preferable not to provide another step portion STP2.

Furthermore, for example, in the second embodiment, it was explained that the step portion STP1 described in the first embodiment is not provided at each corner portion CP of the accommodating portion PKT2, but this explanation does not exclude providing a step portion STP1 at each corner portion CP of the accommodating portion PKT2.

What is claimed is:

1. A method of transporting a semiconductor device, comprising:
(a) preparing the semiconductor device including: a wiring substrate having an upper surface and a lower surface opposite the upper surface, a semiconductor chip mounted on the upper surface of the wiring substrate, and a plurality of external connection terminals provided on the lower surface of the wiring substrate;
(b) preparing a carrier tape having: a first peripheral portion and a second peripheral portion both extending in a first direction, and a plurality of pocket portions that is located between the first peripheral potion and the second peripheral portion in a second direction perpendicular to said first direction, and that is arranged in said first direction;
(c) after the (a) and the (b), placing the semiconductor device in a first pocket portion of the plurality of pocket portions such that the lower surface of the wiring substrate faces a bottom surface of the first pocket portion;
(d) after the (c), attaching a cover tape to the carrier tape so as to cover the semiconductor device placed in the first pocket portion; and
(e) after the (d), transporting the carrier tape containing the semiconductor device,
wherein a planar shape of the wiring substrate is quadrangular,
wherein, in plan view, the first pocket portion includes:
four corner portions where a first step portion is formed; and
four side portions each located between two of the four corner portions, and where a first protruding portion and a second protruding portion are formed, the two being adjacent to each other in either the first direction or the second direction,
wherein, in cross-sectional view, the first step portion has an upper surface positioned above the bottom surface of the first pocket portion, and positioned below an upper surface of each of the first peripheral portion and the second peripheral portion,
wherein, in plan view, a tip portion of the first protruding portion protruding towards an inside of the first pocket portion from a first side portion of the four side portions and a tip portion of the second protruding portion protruding towards the inside of the second pocket portion from the first side portion are different from each other,
wherein, in plan view, a width of the tip portion of the second protruding portion is smaller than a width of the tip portion of the first protruding portion,
wherein, in plan view, a protrusion amount of the second protruding portion from the first side portion is larger than a protrusion amount of the first protruding portion from the first side portion, and
wherein the semiconductor device placed in the first pocket portion in the (c) is spaced apart from the first protruding portion, and the lower surface of the wiring substrate is in contact with the upper surface of the first step portion.

2. The method according to claim 1,
wherein the semiconductor chip has a main surface, a plurality of electrode pads formed on the main surface, and a back surface opposite the main surface,
wherein the semiconductor chip is mounted on the wiring substrate via a plurality of bump electrodes such that the main surface of the semiconductor chip faces the upper surface of the wiring substrate, and
wherein a heat dissipation plate made of a metal member is fixed onto the back surface of the semiconductor chip.

3. The method according to claim 1,
wherein the wiring substrate is a glass epoxy substrate, and
wherein the carrier tape is made of a resin material mixed with carbon.

4. The method according to claim 1, wherein each of the first peripheral portion and the second peripheral portion has a plurality of through-holes arranged in the first direction

5. The method according to claim 1,
wherein the carrier tape prepared in the (b) further includes a second step portion provided, in the second direction, between the first pocket portion in which the first step portion is formed and the first and second peripheral portions,
wherein, in cross-sectional view, the second step portion has an upper surface that is positioned above the upper surface of the first step portion, and that is positioned below the upper surfaces of the first and second peripheral portions, and
wherein in the (d), the cover tape is attached to the upper surface of the second step portion.

6. The method according to claim 1, wherein a planar shape of the first step portion is an L-shape along two sides of four sides of the wiring substrate, the two sides being adjacent to each other.

7. The method according to claim 1, wherein, in plain view, the second protruding portion is located at both end portions of the first side portion so as to sandwich the first protruding portion therebetween.

8. The method according to claim 1,
wherein, in cross-sectional view, the second protruding portion has: a first portion that connects to the bottom surface of the first pocket portion; and a second portion that connects to the first portion,
wherein an inclination of the second portion relative to the bottom surface of the first pocket portion is smaller than an inclination of the first portion relative to the bottom surface of the first pocket portion, and
wherein after the (c), a bending point of the second protruding portion where the first portion and the second portion intersect with each other is positioned between the upper surface of the wiring substrate and the lower surface of the wiring substrate.

9. The method according to claim 1, wherein, in the (e), the carrier tape containing the semiconductor device is transported in such a state that the carrier tape is wound on a reel.

10. A carrier tape comprising:
a first peripheral portion extending in a first direction;
a second peripheral portion extending first direction; and
a plurality of pocket portions located between the first peripheral portion and the second peripheral portion in a second direction perpendicular to the first direction, and arranged in the first direction,
wherein, in plan view, each of the plurality of pocket portions includes:
four corner portions where a first step portion is formed; and
four side portions each located between two of the four corner portions, and where a first protruding portion and a second protruding portion are formed, the two being adjacent to each other in either the first direction or the second direction,
wherein, in cross-sectional view, the first step portion has an upper surface positioned above the bottom surface of each of the plurality of pocket portions, and positioned below an upper surface of each of the first peripheral portion and the second peripheral portion,
wherein, in each of the plurality of pocket portions, a tip portion of the first protruding portion protruding towards an inside of the first pocket portion from a first side portion of the four side portions and a tip portion of the second protruding portion protruding towards the inside of the second pocket portion from the first side portion are different from each other,
wherein, in plan view, a width of the tip portion of the second protruding portion is smaller than a width of the tip portion of the first protruding portion, and
wherein, in plan view, a protrusion amount of the second protruding portion from the first side portion is larger than a protrusion amount of the first protruding portion from the first side portion.

11. The carrier tape according to claim 10 is made of a resin material mixed with carbon.

12. The carrier tape according to claim 10, wherein each of the first peripheral portion and the second peripheral portion has a plurality of through-holes arranged in the first direction.

13. The carrier tape according to claim 10, further comprising:
a second step portion provided, in the second direction, between the plurality of pocket portions in which the first step portion is formed and the first and second peripheral portions,
wherein, in cross-sectional view, the second step portion has an upper surface that is positioned above the upper surface of the first step portion, and that is positioned below the upper surfaces of the first and second peripheral portions,

14. The carrier tape according to claim 10, wherein a planar shape of the first step portion is an L-shape.

15. The carrier tape according to claim 10, wherein, in plain view, the second protruding portion is located at both end portions of the first side portion so as to sandwich the first protruding portion therebetween.

16. The carrier tape according to claim 10,
wherein, in cross-sectional view, the second protruding portion has: a first portion that connects to the bottom surface of each of the plurality of pocket portions; and a second portion that connects to the first portion, and
wherein an inclination of the second portion relative to the bottom surface of each of the plurality of pocket portions is smaller than an inclination of the first portion relative to the bottom surface of each of the plurality of pocket portions.

17. A method of transporting a semiconductor device, comprising:
(a) preparing the semiconductor device including: a wiring substrate having an upper surface and a lower surface opposite the upper surface, a semiconductor chip mounted on the upper surface of the wiring substrate, and a plurality of external connection terminals provided on the lower surface of the wiring substrate;
(b) preparing a carrier tape having: a first peripheral portion and a second peripheral portion both extending in a first direction, and a plurality of pocket portions that is located between the first peripheral potion and the second peripheral portion in a second direction perpendicular to said first direction, and that is arranged in said first direction;
(c) after the (a) and the (b), placing the semiconductor device in a first pocket portion of the plurality of pocket portions such that the lower surface of the wiring substrate faces a bottom surface of the first pocket portion;
(d) after the (c), attaching a cover tape to the carrier tape so as to cover the semiconductor device placed in the first pocket portion; and
(e) after the (d), transporting the carrier tape containing the semiconductor device,
wherein a planar shape of the wiring substrate is quadrangular having a corner,
wherein, in plan view, the first pocket portion includes:
four corner portions each having a notch portion; and
four side portions each located between two of the four corner portions, the two being adjacent to each other in either the first direction or the second direction,
wherein a planar shape of two sides of the notch portion draws an arc so as to curve from each of a first side portion and a second side portion, which are adjacent to the notch portion, towards an apex of the notch portion,
wherein the notch portion is provided such that a distance between the two sides of the notch portion gradually decreases towards the apex of the notch portion, and
wherein the semiconductor device placed in the first pocket portion in the (c) is in contact with the four side portions, and the corner of the wiring substrate is located within the notch portion.

18. The method according to claim 17,
wherein the semiconductor chip has a main surface, a plurality of electrode pads formed on the main surface, and a back surface opposite the main surface,
wherein the semiconductor chip is mounted on the wiring substrate via a plurality of bump electrodes such that the main surface of the semiconductor chip faces the upper surface of the wiring substrate, and
wherein a heat dissipation plate made of a metal member is fixed onto the back surface of the semiconductor chip.

19. The method according to claim 17,
wherein the wiring substrate is a glass epoxy substrate, and
wherein the carrier tape is made of a resin material mixed with carbon.

20. The method according to claim 17, wherein the planar shape of the two sides of the notch portion draws the arc so as to curve from each of the first side portion and the second side portion to the apex of the notch portion without having a bending point therebetween.
